(19) United States
(12) Patent Application Publication
(10) Pub. No.: US 2002/0013031 A1
(43) Pub. Date: Jan. 31, 2002

(54) METHOD OF IMPROVING THE RELIABILITY OF GATE OXIDE LAYER

(76) Inventors: KUEN-JIAN CHEN, HSINCHU HSIEN (TW); HORNG-BOR LU, HSINCHU (TW)

Correspondence Address: DANIEL R MCCLURE, THOMAS KAYDEN HORSTEMEYER & RISLEY, 100 GALLERIA PARKWAY NW, SUITE 1500, ATLANTA, GA, 30339

(21) Appl. No.: 09/246,491

(22) Filed: Feb. 9, 1999

(51) Int. Cl. H01L 21/336; H01L 21/28; H01L 21/4763

(52) U.S. Cl. 438/287; 438/624

(57) ABSTRACT

A method of improving the reliability of a gate oxide layer. A substrate has a gate formed thereon and a dielectric layer is formed on the substrate. Metal interconnects are formed on the dielectric layer. A liner insulated layer is formed by LPCVD, APCVD or PECVD, for example, to cover the dielectric layer and the interconnects. An inter-metal dielectric layer is formed on the liner insulated layer by HDPCVD.

### BACKGROUND OF THE INVENTION

1. Field of the Invention

The invention relates to a method to improve the reliability of a gate oxide layer, and more particularly to a method to modify the inter-metal dielectric (IMD) stack, thereby improving the reliability of the gate oxide layer.

2. Description of the Related Art

Referring to FIG. 1, in the fabrication of gate structure 100 of MOS, a thin gate oxide layer 104 is formed on a semiconductor substrate 102. A layer of polysilicon is then formed on the gate oxide layer 104 for use as a gate 106. To manufacture multilevel interconnects 108a, 108b, a dielectric layer 110 is necessarily deposited over the gate 106 to serve as an insulator between the gate 106 and the interconnects 108a, 108b, and the gate is electrically connected with the interconnects 108a by the formation of a via 112. Since the high density plasma chemical vapor deposition (HDPCVD) is good for depositing a dielectric material with high aspect ratio metal spacing, it is generally employed to form an IMD 114 to cover the interconnects 108a, 108b. However, the gate oxide layer 104 is damaged after the IMD 114 is deposited by HDPCVD. FIG. 2 illustrates the frequency of breakdown charge (Q_{BD}) of the gate oxide layer 104 and the IMD 114 formed by HDPCVD. As shown in FIG. 2, when the breakdown charge is lower than 1 coul/cm², the frequency of the gate oxide layer 104 defect is relatively high.

The major reason that causes the gate oxide layer 104 to be damaged includes an antenna effect. The charged particles in the high density plasma are attracted by the gate 106 and penetrate the IMD 114 to reach to the gate 104. A part of the charged particles even reach the gate oxide layer 104 and destroy the dense structure of the gate oxide layer 104. As a result, this behavior causes the gate oxide layer 104 breakdown to occur.

In addition, the charged particles in the plasma produce strong ultra-violet rays and short wave length rays when the deposition is carried out by the HDPCVD. These rays are capable of penetrating through the surrounding dielectric material of the gate oxide layer 104 and being absorbed by the gate oxide layer 104. The ultra-violet rays and short wave length rays with high energy activate the charged particles trapped in the gate oxide layer 104, in the interface between the gate oxide layer 104 and the substrate 104, and between the gate oxide layer 104 and the gate 106, such that the excited electron-hole pair destroy the structure of the gate oxide layer 104. Therefore, the quality of the device is decreased and the productivity is lower while the gate oxide layer 104 is damaged.

### SUMMARY OF THE INVENTION

Therefore, the invention is directed towards a method of improving the reliability of the gate oxide layer. A dielectric layer is formed on a substrate at least having a gate. An interconnect is then formed on the dielectric layer. The interconnect and the dielectric layer are covered with a liner insulated layer, which is formed by low pressure chemical vapor deposition (LPCVD), atmospheric pressure chemical vapor deposition (APCVD) or plasma enhanced chemical vapor deposition (PECVD), for example. An IMD layer is formed on the liner insulated layer by HDPCVD.

The liner insulated layer enables the charge particles to be blocked and prevented from reaching the gate oxide layer while the IMD is carried out by HDPCVD. Accordingly, the defect of the gate oxide layer can be avoided, to thereby enhance the reliability of the gate oxide layer.

It is to be understood that both the foregoing general description and the following detailed description are exemplary and explanatory only and are not restrictive of the invention, as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is schematic, cross-sectional view illustrating a semiconductor device structure with an inter-metal dielectric formed by HDPCVD as known in prior art;

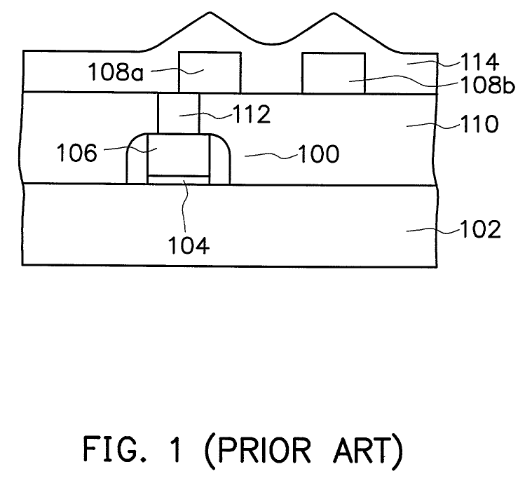

FIG. 2 shows a frequency of breakdown charge for a gate oxide layer of a semiconductor device structure as known in prior art;

FIG. 3 is a schematic, cross-sectional view illustrating a semiconductor device structure in a preferred embodiment according to the invention; and

FIG. 4 shows a frequency of breakdown charge for a gate oxide layer of the semiconductor device structure in a preferred embodiment according to the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

This invention includes forming a liner insulated layer on interconnects by LPCVD or APCVD prior to the formation of the IMD formed by HDPCVD. Since the liner insulated layer is not formed in a high density plasma environment, the antenna effect cannot be induced. The IMD layer with a better deposition performance can be subsequently formed in the high density plasma environment due to the fabrication of the liner insulated layer. As a result, the breakdown of the gate oxide layer is prevented by the insulation of the insulated layer.

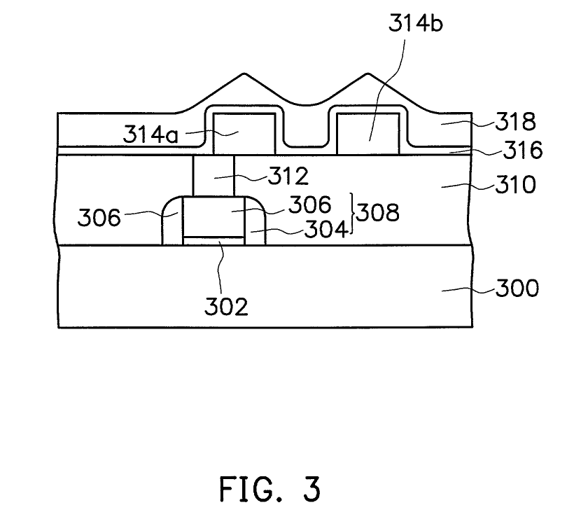

FIG. 3 is a schematic, cross-sectional view of a semiconductor device structure in a preferred embodiment according to the invention. Referring to FIG. 3, a substrate 300 has isolation structures (not shown) formed thereon to define the active area. A gate oxide layer 302 is formed on the substrate 300 by thermal oxidation and a gate 304 is formed on the gate oxide layer 302. The gate 304 is made of conductive materials, such as polysilicon or polycide. An insulated spacer 306, such as oxide, is formed on the sidewall of the gate 304, and a source/drain region (not shown) is formed in the substrate 300. The gate 304 and the insulated spacer 306 are used as a gate structure 308.

A dielectric layer 310 is formed on the substrate 300. For example, chemical vapor deposition (CVD) is used to form TEOS oxide or planarized material, such as PSG or BPSG. Referring to FIG. 3 again, a via 312 is formed within the dielectric layer 310 and metal interconnects 314a, 314b are formed on the dielectric layer 310. The via 310 allows the gate 304 to be electrically connected with the metal interconnect 314a. The via 312 and the metal interconnects 314a, 314b can be formed by damascene or another conventional process well known to those skilled in the art.

A liner insulated layer 316 conformal to the substrate 300 with the device structure is formed on the dielectric layer 310 and the metal interconnects 314a, 314b. The liner insulated layer 316 has a thickness of about 10-10000 angstroms and can be formed by LPCVD, APCVD or PECVD to obtain an insulated material, such as oxide, nitride, borate, or a composite film formed from two of the above materials, such as nitride-borate, silicon-oxy-nitride (SiOₓN_{y}). Since the liner insulated layer 316 is not formed in a high density plasma condition, the deposition chamber does not generate charged particles. Therefore, the gate oxide layer 302 cannot be destroyed by the charges to cause breakdown.

The high density plasma chemical vapor deposition (HDPCVD), for example, is utilized to formed an inter-metal dielectric layer 318 on the liner insulated layer 316 to obtain a better deposition performance. Though the IMD layer 318 is formed in a high density plasma environment, the charged particles in the plasma are screened by the liner insulated layer 316. Therefore, the charged particles cannot reach the gate oxide layer 302 through the metal interconnects 314a, 314b, via 312 and gate 306. The breakdown of the gate oxide layer 302 is avoided, thereby improving the reliability of the gate oxide layer 302.

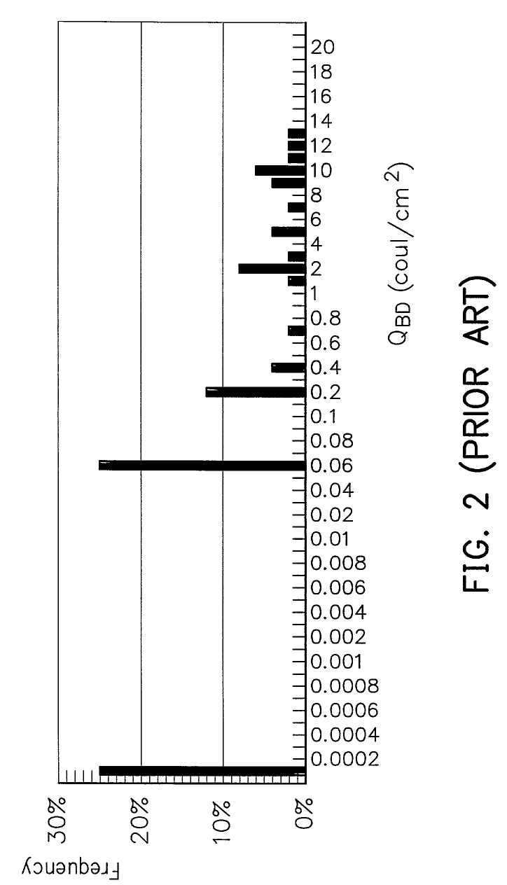

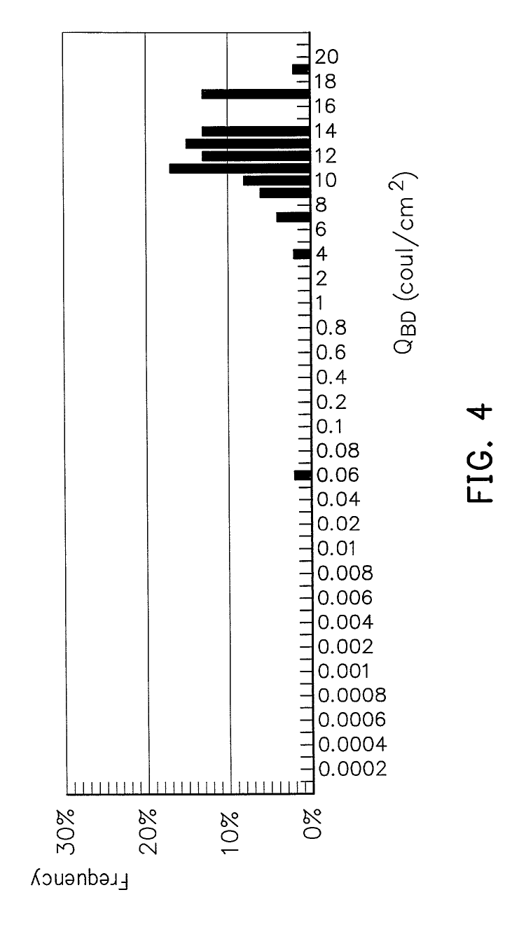

FIG. 4 shows the frequency of a gate oxide breakdown, in which a semiconductor device structure having the gate oxide layer is formed by the foregoing process. According to this invention, the liner insulated layer 316 is formed over the substrate 300 by PECVD prior to the formation of the IMD layer 318. When the breakdown charge is lower than 1 coul/cm², the frequency of the gate oxide layer 302 breakdown is far less than that of prior art (FIG. 2) without the liner insulated layer. The fabricating process of this invention dramatically reduces the frequency of the gate oxide breakdown; thus the reliability of the gate oxide layer is improved.

This invention forms a liner insulated layer conformal to the structure on the substrate before HDPCVD is performed, such that the particles generated in plasma can be prevented from penetrating the gate oxide layer to cause breakdown. The reliability of the gate oxide layer is ameliorated, the yield of the devices is increased and the life of the device is prolonged.

Other embodiment of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of improving the reliability of the gate oxide layer, adapted for a substrate having a gate structure and a dielectric layer disposed between the substrate and interconnects, comprising:
forming a liner insulated layer over the substrate; and
forming an inter-metal dielectric layer on the liner insulated layer.

2. The method according to claim 1, wherein a material for the liner insulated layer is selected from a group consisting of oxide, nitride, borate, nitride-borate and silicon-oxy-nitride.

3. The method according to claim 1, wherein the thickness of the liner insulated layer is in a range of about 10-10000 angstroms.

4. The method according to claim 1, wherein the liner insulated layer is formed by low pressure chemical vapor deposition.

5. The method according to claim 1, wherein the liner insulated layer is formed by atmospheric pressure chemical vapor deposition.

6. The method according to claim 1, wherein the liner insulated layer is formed by plasma enhanced chemical vapor deposition.

7. The method according to claim 1, wherein the inter-metal dielectric layer is formed by high density plasma chemical vapor deposition.

8. A method of fabricating a semiconductor device, thereby improving the reliability of a gate oxide layer, comprising:
providing a gate structure at least having a gate formed on the gate oxide layer;
forming a dielectric layer to cover the gate structure;
forming metal interconnects on the dielectric layer;
forming a conformal insulated layer on the dielectric layer and the interconnects; and
forming an inter-metal dielectric layer on the conformal insulated layer.

9. The method according to claim 10, wherein a material for the conformal insulated layer is selected from a group consisting of oxide, nitride, borate, nitride-borate and silicon-oxy-nitride.

10. The method according to claim 10, wherein the thickness of the conformal insulated layer is in a range of about 10-10000 angstroms.

11. The method according to claim 10, wherein the liner insulated layer is formed by low pressure chemical vapor deposition.

12. The method according to claim 10, wherein the liner insulated layer is formed by atmospheric pressure chemical vapor deposition.

13. The method according to claim 10, wherein the liner insulated layer is formed by plasma enhanced chemical vapor deposition.

14. The method according to claim 10, wherein the inter-metal dielectric layer is formed by high density plasma chemical vapor deposition.
